(19) United States
(12) Patent Application Publication
(10) Pub. No.: US 2010/0006143 A1
(43) Pub. Date: Jan. 14, 2010

(54) Solar Cell Devices

(76) Inventor: Roger E. Welser, Providence, RI (US)

Correspondence Address: HAMILTON, BROOK, SMITH & REYNOLDS, P.C., 530 VIRGINIA ROAD, P.O. BOX 9133, CONCORD, MA, 01742-9133, US

(21) Appl. No.: 12/148,945

(22) Filed: Apr. 23, 2008

Related U.S. Application Data
(60) Provisional application No. 60/926,325, filed on Apr. 26, 2007.

(51) Int. Cl. H01L 31/06; H01L 31/0232; H01L 31/18

(52) U.S. Cl. 136/255; 438/72; 438/73; 438/94; 136/262; 136/252; 257/E21.211; 257/E31.127; 977/755; 977/948; 977/774

(57) ABSTRACT

A solar cell device includes a p-n diode component over a substrate, the p-n diode component including at least one subcell, each subcell including an n-type semiconductor layer and a p-type semiconductor layer to form a p-n junction. The solar cell device further includes at least two features selected from: i) a nano-structured region between at the p-n junction of at least one subcell; ii) an n-type and/or a p-type layer of at least one subcell that includes a built-in quasi-electric field; and iii) a photon reflector structure. Alternatively, the solar cell device includes at least two subcells, and further includes a nano-structured region at the p-n junction of at least one of the subcells, wherein the subcells of the solar cell device are connected in parallel to each other by the p-type or the n-type semiconductor layer of each subcell. Alternatively, the solar cell device further includes a nano-structured region at the p-n junction of at least one subcell, wherein the nano-structured region includes i) a plurality of quantum dots or quantum wells that include InN or InGaN, the quantum dots or quantum wells embedded within a wide band gap matrix that includes InGaN, GaN, or AlGaN, or ii) a plurality of quantum dots or quantum wells that include InAs, GaAs or InGaAs, the quantum dots or quantum wells embedded within a wide band gap matrix that includes InGaP, GaAsP, AlGaAs, AlGaInAs or AlGaInP.

### RELATED APPLICATION

This application claims the benefit of U.S. Provisional Application No. 60/926,325, filed on Apr. 26, 2007. The entire teachings of the above application are incorporated herein by reference.

### GOVERNMENT SUPPORT

The invention was supported, in whole or in part, by a grant NNC07QA82P from the Small Business Technology Transfer (STTR) Program of the U.S. National Aeronautics and Space Administration (NASA). The Government has certain rights in the invention.

### BACKGROUND OF THE INVENTION

Photovoltaic solar arrays provide an excellent source of power for commercial and military spacecraft and hold great promise as a sustainable, environmentally friendly energy source for the 21st century. While photovoltaics (PV) currently provide a minuscule percentage of the world's energy needs, it is a surprisingly large and rapidly growing industry. The worldwide PV market has been growing at over 30% annually since the late 1990s, and now generates well over $5 billion (US) per year in revenue.

The performance of photovoltaic solar arrays and the underlying solar cell devices are typically characterized by the solar electric conversion efficiency. The conversion efficiency achieved in traditional single-junction semiconductor solar cells is typically limited to less than 25%. Photons with energies below the band gap of the semiconductor active layers of such a single-junction semiconductor solar cell device pass right through the device and do not contribute to the photon generated current. The voltage of operation in a solar cell device generally is also limited by the semiconductor band gap. High energy photons can be collected but are extracted at a lower voltage, with the difference in energy between the photon and the semiconductor band gap lost as heat.

Multi-junction cells can increase the operating voltage, and hence the efficiency, of traditional solar cells by stacking multiple p-n junctions of different semiconductor materials into one two-terminal device. For example, InGaP/GaAs/Ge three-junction cells have achieved one-sun solar conversion efficiencies over 30%, and are approaching 40% under concentrated light. While these state-of-the-art multi-junction cells are suitable for some applications, fundamental issues often hamper this technical approach to high performance solar photovoltaic devices. First, the current-matching requirements of series-connected devices make multi-junction cells highly susceptible to changes in the solar spectrum throughout the day and from location to location. Second, multi-junction cells require the growth of extra-thick epitaxial layers, which adds to the already high material costs of these advanced cells. Finally, brute-force attempts to improve the performance of multi-junction III-V solar cells require stacking even more junctions together, a daunting task facing diminishing returns. Of particular note, lattice matching of Groups III-V semiconductor materials generally constrains the implementation of the multi-junction approach, often forcing compromises in terms of device performance and device cost.

Therefore, there is a need for developing new solar cell devices that can address one or more of the aforementioned problems associated with conventional solar cell devices.

### SUMMARY OF THE INVENTION

The present invention generally is directed to a solar cell device and to a method of preparing a solar cell device.

In one embodiment, the present invention is directed to a solar cell device that includes a substrate and a p-n diode component over the substrate. The p-n diode component includes at least one subcell that includes an n-type semiconductor layer and a p-type semiconductor layer to form a p-n junction. The solar cell device further includes at least two features selected from: i) a nano-structured region at the p-n junction between the n-type and the p-type semiconductor layers of at least one subcell, the nano-structured region including a plurality of quantum dots or quantum wells that are embedded within a band gap matrix that has a band gap greater than that of the quantum dots or the quantum wells embedded therein; ii) an n-type or a p-type semiconductor layer of at least one subcell that includes either a compositional grade or a doping grade, or both, thereby having a built-in quasi-electric field; and iii) a photon reflector structure between the substrate and the p-n diode component, over the substrate and opposite the p-n diode component, or over the p-n diode component and opposite the substrate. The solar cell device can include a single p-n junction subcell. Alternatively, the solar cell device can include multiple p-n junction subcells connected to each other in parallel or in series.

In another embodiment, the present invention is directed to a solar cell device that includes a substrate and a p-n diode component over the substrate. The p-n diode component includes at least one subcell that includes an n-type semiconductor layer and a p-type semiconductor layer to form a p-n junction. The solar cell device further includes a nano-structured region at the p-n junction, the nano-structured region including a plurality of quantum dots or quantum wells that are embedded within a wide band gap matrix that has a band gap greater than that of the quantum dots or the quantum wells embedded therein. The subcells are connected in parallel to each other by the p-type or the n-type semiconductor layer of each subcell.

In yet another embodiment, the present invention is directed to a solar cell device that includes a substrate and a p-n diode component over the substrate. The p-n diode component includes at least one subcell that includes an n-type semiconductor layer and a p-type semiconductor layer to form a p-n junction. The solar cell device further includes a nano-structured region at the p-n junction of at least one subcell. The nano-structured region includes a plurality of quantum dots or quantum wells that are embedded within a wide band gap matrix that has a band gap greater than that of the quantum dots or the quantum wells embedded therein, wherein i) the quantum dots or the quantum wells include InN or InGaN, and the wide band gap matrix includes InGaN, GaN, or AlGaN, or ii) the quantum dots or the quantum wells include InAs, GaAs or InGaAs, and the wide band gap matrix includes InGaP, GaAsP, AlGaAs, AlGaInAs or AlGaInP.

In yet another embodiment, the present invention is directed to a method of preparing a solar cell device that includes a substrate and a p-n diode component over the substrate. The method includes at least two steps selected from:

a) forming a nano-structured region at a p-n junction between an n-type semiconductor layer and a p-type semiconductor layer of at least one subcell of the p-n diode component of the solar cell device, the nano-structured region including a plurality of quantum dots or quantum wells that are embedded within a band gap matrix that has a band gap greater than that of the quantum dots or the quantum wells embedded therein;
b) forming an n-type and/or a p-type semiconductor layer of at least one subcell of a p-n diode component of the solar cell device, the n-type and/or p-type semiconductor layer including either a compositional grade or a doping grade, or both, thereby having a built-in quasi-electric field; and
c) forming a photon reflector structure between the substrate and the p-n diode component, over the substrate opposite the p-n diode component, or over the p-n diode component opposite the substrate, the p-n diode component including at least one subcell that includes an n-type semiconductor layer and a p-type semiconductor layer to form a p-n junction.

In yet another embodiment, the present invention is directed to a method of preparing a solar cell device. The method includes the step of forming a p-n diode component over a substrate. The p-n diode component includes at least two subcells, each subcell including an n-type semiconductor layer and a p-type semiconductor layer to form a p-n junction. The p-n diode component further includes a nano-structured region at the p-n junction, the nano-structured region including a plurality of quantum dots or quantum wells that are embedded within a wide band gap matrix that has a band gap greater than that of the quantum dots or the quantum wells embedded therein. The subcells are connected in parallel to each other by the p-type or the n-type semiconductor layer of each subcell.

In yet another embodiment, the present invention is directed to a method of preparing a solar cell device. The method includes the step of forming a p-n diode component over a substrate. The p-n diode component includes at least one subcell, each subcell including an n-type semiconductor layer and a p-type semiconductor layer to form a p-n junction. The p-n diode component further includes a nano-structured region at the p-n junction, the nano-structured region including a plurality of quantum dots or quantum wells that are embedded within a wide band gap matrix that has a band gap greater than that of the quantum dots or the quantum wells embedded therein, wherein i) the quantum dots or the quantum wells include InN or InGaN, and the wide band gap matrix includes InGaN, GaN, or AlGaN, or ii) the quantum dots or the quantum wells include InAs, GaAs or InGaAs, and the wide band gap matrix includes InGaP, GaAsP, AlGaAs, AlGaInAs or AlGaInP.

The solar cell device of the invention can enhance the photovoltaic conversion efficiency of traditional semiconductor solar cells while minimizing the manufacturing costs. In particular, the present invention employing quantum dots or wells embedded within the wide band gap matrix can enhance the performance of InGaP/GaAs/Ge solar cells currently used for space power. In addition, the present invention employing built-in quasi-electric fields can offset degradations in material quality due to lattice mismatch and can provide improved device performance. For example, in one embodiment of the present invention, built-in quasi-electric fields, which can be generated by adding doping and/or compositional grades to both of the InGaP and InGaAs junctions, can be added to the InGaAs subcell of InGaP/InGaAs/Ge multi-junction solar cell device to improve the effective minority carrier diffusion length.

### BRIEF DESCRIPTION OF THE DRAWINGS

FIG. 1 is a schematic drawing showing certain components of a solar cell device of the invention.

FIG. 2 is a band diagram of one embodiment of a solar cell device of the invention.

FIG. 3 is a band diagram illustrating three possible mechanisms for converting photons into electrons in a solar cell of the invention.

FIG. 4 shows a cross-sectional layer structure of a solar cell device according to one embodiment of the invention in which nitride-based semiconductor materials are employed.

FIG. 5 shows a cross-sectional layer structure of a solar cell device according to one embodiment of the invention in which arsenide-based and/or phosphide-based materials are employed.

FIG. 6A shows a cross-sectional layer structure of a solar cell device according to one embodiment of the invention in which two subcells are connected in series.

FIG. 6B shows the solar cell device of FIG. 6A in energy.

FIG. 7A shows a cross-sectional layer structure of a solar cell according to one embodiment of the invention in which two subcells are connected in parallel.

FIG. 7B shows a cross-sectional layer structure of a solar cell according to another embodiment of the invention in which two subcells are connected in parallel.

FIG. 7C shows a cross-sectional layer structure of a solar cell according to another embodiment of the invention in which two subcells are connected in parallel.

FIG. 7D shows a cross-sectional layer structure of a solar cell according to another embodiment of the invention in which two subcells are connected in parallel.

FIG. 8A shows a cross-sectional layer structure of a solar cell according to one embodiment of the invention in which two subcells are connected in parallel by a common p-type semiconductor layer.

FIG. 8B shows the solar cell device of FIG. 8A in energy.

### DETAILED DESCRIPTION OF THE INVENTION

The foregoing will be apparent from the following more particular description of example embodiments of the invention, as illustrated in the accompanying drawings in which like reference characters refer to the same parts throughout the different views. The drawings are not necessarily to scale, emphasis instead being placed upon illustrating embodiments of the present invention.

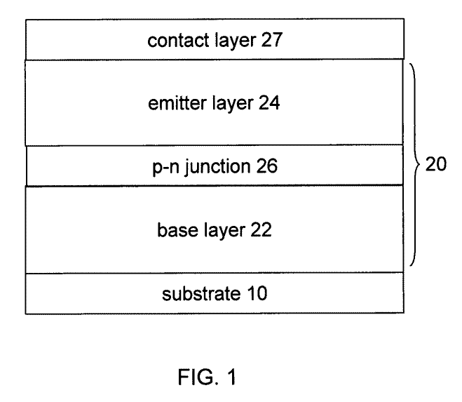

As shown in FIG. 1, typically, the solar cell devices of the invention include substrate 10 and p-n diode component 20 over substrate 10. Generally, p-n diode component 20 includes at least one subcell, wherein each subcell includes base layer 22 and emitter layer 24. Although only one subcell is shown in FIG. 1, a plurality of such subcells can be employed in the invention. Base layer 22 and emitter layer 24 are p-type and n-type semiconductor layers, respectively, or vice versa, forming a p-n diode. P-n junction 26 is formed at the interface of base layer 22 and emitter layer 24. FIG. 1 also shows contact layer 27. The contact layer 27 can be a metal layer or a semiconductor layer, or both.

In the invention, optionally, one or more of metal contact layers can be employed at the bottom of substrate 10 and over the top emitter layer 24 of the device. Any electrically conductive metallic materials (e.g., Cu, Au, etc.) can be employed for the metal contact layers in the invention.

Suitable examples of substrates 10 include sapphire, silicon, GaAs, GaP, ZnSe and ZnS substrates. Alternatively, substrate 10 can include germanium.

Any suitable semiconductor materials, such as GaN- (e.g., AlGaN), AlN-, InN-, GaAs-, AlAs-, InAs-, GaP- (e.g., GaInP, AlInGaP), InP-, InGaP- and AlP-based materials, and alloys thereof, can be used for base and emitter layers 22 and 24 of the solar cell device of the invention. GaN generally has an energy gap over 3.4 eV, while the band gap of AlN generally exceeds 6 eV. A p-n diode employing AlGaN material can achieve operating voltages well over 2 V when utilized as a solar cell. On the other hand, InN materials are relatively narrow band gap semiconductors with an energy gap in the infrared region, and generally suitable for the absorption of lower energy photons. InGaP materials, which are generally lattice matched to GaAs and have an energy gap near 1.9 eV, are generally used to produce heterojunction bipolar transistors, light emitting diodes, and multi-junction solar cells. A p-n diode employing InGaP, AlInGaP, or AlGaAs alloys can achieve operating voltages approaching 1.5 V when utilized as a solar cell. InAs-based materials (e.g., InAs or InGaAs) have an energy gap near 0.4 eV, which indicates InAs-based quantum structures can absorb much of the solar spectrum.

Optionally, one or more nucleation layers can be employed in the invention between substrate 10 and base layer 22.

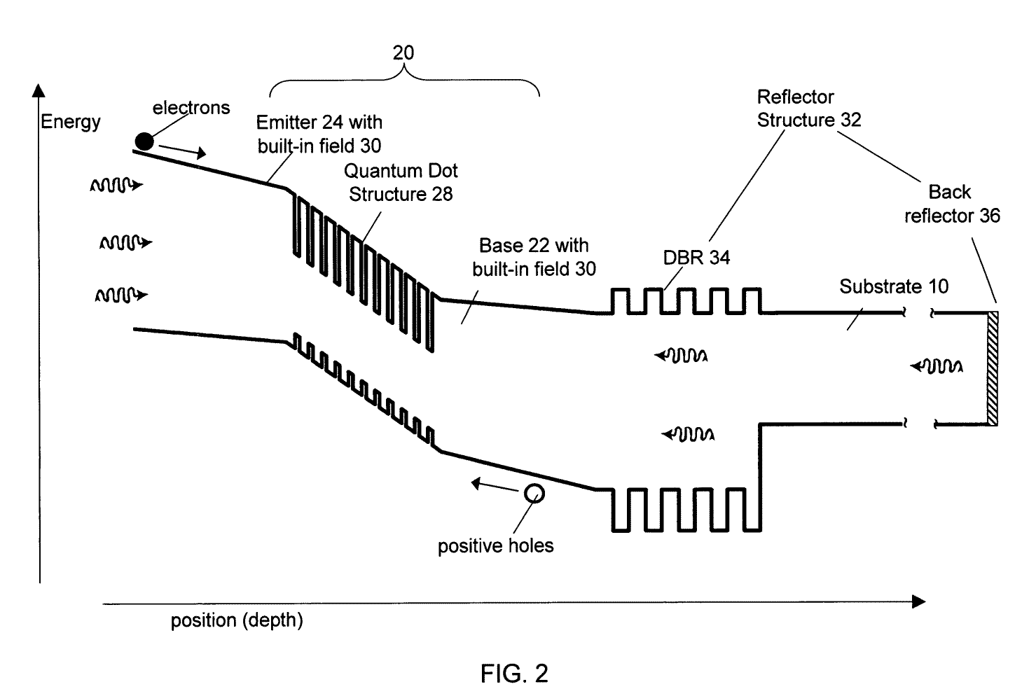

In a first embodiment, as shown in FIG. 2, a solar cell device of the invention further includes at least two features selected from: i) nano-structured region 28 at the p-n junction between base layer 22 and emitter layer 24 of at least one subcell, nano-structured region 28 including a plurality of quantum dots or quantum wells that are embedded within a band gap matrix that has a band gap greater than that of the quantum dots or the quantum wells embedded therein; ii) base layer 22 and/or emitter layer 24 of at least one subcell that includes either a compositional grade or a doping grade, or both, thereby having built-in quasi-electric field 30; and iii) photon reflector structure 32 between substrate 10 and p-n diode component 20, over substrate 10 and opposite p-n diode component 20, or over p-n diode component 20 and opposite substrate 10.

In a first aspect of the first embodiment, at least one subcell includes nano-structured region 28 at the p-n junction between base layer 22 and emitter layer 24 (see FIG. 2). Nano-structured region 28 typically includes a plurality of quantum dots or quantum wells that are embedded within a wide band gap matrix that has a band gap greater than that of the quantum dots or the quantum wells embedded therein.

As used herein, the term “wide band gap material” means a semiconductor material having a band gap greater than that of the quantum dots or wells embedded therein. Typically, a wide band gap material has a band gap energy of greater than about 1.6 eV. Generally a wide band gap material (energy gap>1.6 eV) is desirable to achieve low dark currents that are relatively insensitive to temperature and radiation. Such low dark currents in a p-n diode can provide high operating voltages when the diode is employed as a solar cell with radiation and extreme temperature tolerance.

The Quantum wells and the quantum dots employed in the invention can be formed by any suitable standard material synthesis technique known in the art. Particularly, the quantum dots employed in the invention can be self-assembled by the strain-driven Stranski-Krastanov growth known in the art, for example, in Bruce A. Joyce and Dimitri D. Vvedensky, “Self-organized Growth on GaAs Surfaces,” Materials Science and Engineering R 46 (2004) 127-176 (the entire teachings of which are incorporated herein by reference).

In a specific embodiment, the quantum dots or quantum wells employed in the invention are composed of self-assembled semiconductor material with a lower energy gap than that of the wide band gap matrix, enabling the absorption of photons below the band edge of the wide band gap diode material. The absorption profile of the embedded quantum dots or wells can be tailored by adjusting the composition and dimensions of the individual dots and the number of quantum dot or well layers contained within the p-n junction. The dimensions of the junction depletion region can be adjusted by both the magnitude of the n- and p-type doping adjacent to the junction and by adding un-doped (or intrinsic) material between the n- and p-type layers. The quantum dots or quantum wells embedded within a wide band gap matrix can enhance the current generated by the absorption of photons within the wide band gap p-n junction. Also, such quantum dots or quantum wells can be used to harness photons with energies below the band gap in a two-step process that pumps electrons from the valence band to the conduction band via an intermediate band (see, for example, U.S. Pat. No. 6,444,897, the entire teachings of which are incorporated herein by reference).

In another specific embodiment, InGaN, GaN or AlGaN is used as the wide band gap matrix, and InN or InGaN is used as the quantum dot or well material. In yet another aspect of the first embodiment, InGaP, GaAsP, AlGaAs, AlGaInAs or AlGaInP is used as the wide band gap matrix, and InAs or InGaAs is used as the quantum dot or well material.

In yet another specific embodiment, the quantum dots or the quantum wells include InN or InGaN, and the wide band gap matrix includes InGaN, GaN or AlGaN; and base layer 22 and/or emitter layer 24 includes a nitride material. Suitable specific examples of nitride materials include AlN, GaN, InN, InGaN or AlGaN, or an alloy thereof. In yet another specific embodiment, the quantum dots or the quantum wells include InN or InGaN, and the wide band gap matrix includes InGaN, GaN or AlGaN; and base layer 22 and/or emitter layer 24 includes InGaN, GaN or AlGaN or an alloy thereof. In these embodiments, the InN and the InGaN quantum dots or the quantum wells are preferably self-assembled by the strain-driven Stranski-Krastanov growth known in the art.

In yet another specific embodiment, the quantum dots or the quantum wells include InAs, GaAs or InGaAs; the wide band gap matrix includes InGaP, GaAsP, InGaP, AlGaAs, AlGaInAs or AlGaInP; and base layer 22 and/or emitter layer 24 includes an arsenide or phosphide material. Suitable specific arsenide or phosphide materials include GaAs, AlAs, InAs, GaP, InP, AlP, InGaAs, InGaP, GaAsP, AlGaAs, AlGaInAs or AlGaInP, or an alloy thereof. In yet another specific embodiment, the quantum dots or the quantum wells include InAs or InGaAs; the wide band gap matrix includes InGaP, GaAsP, AlGaAs, AlGaInAs or AlGaInP; and base layer 22 and/or emitter layer 24 includes InGaP, GaAsP, AlGaAs, AlGaInAs or AlGaInP, or an alloy thereof. In yet another specific embodiment, the quantum dots or the quantum wells include InAs or InGaAs; the wide band gap matrix includes InGaP, GaAsP, AlGaAs, AlGaInAs or AlGaInP; and base layer 22 and/or emitter layer 24 includes GaAs, AlAs, InAs, GaP, InP, or an alloy thereof. In these embodiments, InAs, GaAs and InGaAs quantum dots or the quantum wells are preferably self-assembled by the strain-driven Stranski-Krastanov growth known in the art.

In a second aspect of the first embodiment, at least one of base layer 22 and emitter layer 24 (n-type and p-type semiconductor layers, or vice versa) of at least one subcell includes built-in quasi-electric field 30 (see FIG. 2). Built-in quasi-electric fields 30 of emitter and base layers 22 and 24 can each and independently be generated by grading the energy-gap (i.e., compositional grading) and/or by grading the doping level (i.e., doping grading), of the emitter and base layers, respectively. For example, built-in quasi-electric field 30 of base layer 22 can be generated by grading either the composition of the base layer or the doping level of the base layer, or both. Similarly, built-in quasi-electric field 30 of emitter layer 22 can be generated by grading either the composition of the emitter layer or the doping level of the emitter layer, or both. Such built-in quasi-electric field 30 can accelerate photon generated minority carriers into the depletion region of the p-n junction. Also, when quantum dots (or quantum wells) are embedded within a wide band gap matrix, built-in quasi-electric field 30 can minimize or reduce unwanted capturing of carriers in the quantum dots (or quantum wells). Also, built-in quasi-electric field 30 can increase the effective diffusion length of minority carriers within n- and p-type wide band gap materials (see, for example, Sassi, “Theoretical Analysis of Solar Cells Based on Graded Band-Gap Structures,” Journal of Applied Physics, vol. 54, pp. 5421-5427, September 1983, the entire teachings of which are incorporated herein by reference). Such enhancement in the diffusion length is particularly beneficial when a wide band gap material, which is lattice mismatched to the substrate, is used either to optimize absorption profiles or lower manufacturing costs.

In one specific embodiment, base layer 22 and emitter layer 24 are each and independently graded in such a way that minority carriers are push toward their junction. Suitable methods of grading the energy-gap and/or the doping level of the emitter and base layers can be found in the art, for example, in U.S. Pat. Nos. 6,750,480, 6,847,060, 7,186,624 and 7,115,446, the entire teachings of which are incorporated herein by reference.

In a third aspect of the first embodiment, at least one photon reflector structure 32 (see FIG. 2) is employed in the invention. Photon reflector structure 32 can be placed between substrate 10 and p-n diode component 20 (e.g., distributed Bragg reflector (DBR) 34 in FIG. 2). Alternatively, photon reflector structure 32 can be placed over substrate 10 and opposite p-n diode component 20 (e.g., back reflector 36 in FIG. 2). Alternatively, photon reflector structure 32 can be placed over p-n diode component 20 and opposite substrate 10 (e.g., front reflector, not shown in FIG. 2).

Photon reflector structure 32 can increase the optical path length of incident photons within the p-n diode component of the solar cell device of the invention.

Photon reflector structure 32 can include one or more metallic layers. Other suitable examples of photon reflector structures 32 include distributed Bragg reflectors (DBRs), total internal reflectors (TIRs), and omni-directional reflectors (ODRs). The reflectivity of the photon reflector structure can be tuned by adjusting the thickness, composition, and/or number of layers. Suitable examples of DBRs, TIRs and ODRs can be found in the art. For example, suitable examples of DBRs can be found in Gessmann et al., “Omnidirectional Reflective Contacts for Light-Emitting Diodes,” IEEE Electron Device Letters, vol. 24, pp. 683-685, October 2002, the entire teachings of which are incorporated herein by reference. DBRs can be used in particular to reflect photons incident near normal to the epitaxial layers, photons that have the shortest initial path length intersecting with the quantum dot layers.

In one specific embodiment, substrate 10 includes a material that absorbs photons, and the solar cell device is arranged such that photons are incident upon the top of p-n diode component 20. Specifically, in this embodiment, photon reflector structure 32, such as distributed Bragg reflectors (DBRs) 34, can be positioned between substrate 10 and p-n diode component 20.

In another specific embodiment, the solar cell device is arranged such that photons are incident upon the top of p-n diode component 20, and photon reflector structure 32 is positioned at a back side of substrate 10 (e.g., back reflector 36 as shown in FIG. 2), opposite p-n diode component 20. In this embodiment, the photon reflector structure can be added to a metal contact at the bottom of substrate 10, opposite p-n diode component.

In yet another specific embodiment, the solar cell device is arranged such that photons are incident upon the bottom of the device, and photon reflector structure 32 is positioned over p-n diode component 20 (e.g., a front reflector), e.g., at the top of the device. In this embodiment, the photon reflector structure can be added to a metal contact layer (e.g. disposed over contact layer 27 of FIG. 1) at the top of the device.

In yet another specific embodiment, photon reflector structure 32 includes one or more metallic layers. In yet another aspect of the third embodiment, photon reflector structure 32 includes one or more metallic layers, and is disposed over substrate 10 opposite p-n diode component 20. In these embodiments, specifically, substrate 10 includes GaP, ZnSe or ZnS.

In yet another specific embodiment, photon reflector structure 32 includes a distributed Bragg reflector (DBR) of AlAs, AlGaAs, AlGaInP, or AlInP. In yet another specific embodiment, photon reflector structure 32 includes a distributed Bragg reflector (DBR) of AlAs, AlGaAs, AlGaInP, or AlInP, and is disposed between substrate 10 and the p-n diode component 20.

In a fourth aspect of the first embodiment, nano-structured region 28, and base layer 22 that includes either a compositional grade or a doping grade, or both, thereby having built-in quasi-electric field 30, are employed. In a fifth aspect of the first embodiment, nano-structured region 28, and emitter layer 24 that includes either a compositional grade or a doping grade, or both, thereby having built-in quasi-electric field 30, are employed. In a sixth aspect of the first embodiment, nano-structured region 28, and base layer 22 and emitter layer 24, both of which include either a compositional grade or a doping grade, or both, thereby having built-in quasi-electric field 30, are employed. Features, including specific features, of nano-structured region 28, base layer 22, emitter layer 24 and built-in quasi-electric field 30 are as described above.

In a seventh aspect of the first embodiment, nano-structured region 28 and at least one photon reflector structure 32 are employed. Features, including specific features, of nano-structured region 28 and photon reflector structure 32 are as described above.

In an eighth aspect of the first embodiment, at least one photon reflector structure 32, and base layer 22 that includes either a compositional grade or a doping grade, or both, thereby having built-in quasi-electric field 30, are employed. In a tenth aspect of the first embodiment, nano-structured region 28, and emitter layer 24 that includes either a compositional grade or a doping grade, or both, thereby having built-in quasi-electric field 30, are employed. In an eleventh aspect of the first embodiment, at least one photon reflector structure 32, and base layer 22 and emitter layer 24, both of which include either a compositional grade or a doping grade, or both, thereby having built-in quasi-electric field 30, are employed. Features, including specific features, of photon reflector structure 32, base layer 22, emitter layer 24 and built-in quasi-electric field 30 are as described above.

In a twelfth aspect of the first embodiment of the invention, emitter layer 24 with built-in quasi-electric field 30, nano-structured region 28, base layer 22 with built-in quasi-electric field 30, and at least one photon reflector structure 32 (e.g., DBR 34 and/or back reflector 36) are employed. Features, including specific features, of photon reflector structure 32, base layer 22, emitter layer 24 and built-in quasi-electric field 30 are as described above.

A specific example of the first embodiment is shown in FIG. 2. In the device of FIG. 2, specifically, DBR 34 and back reflector 36 each independently include a material that can reflect photons with energies above the band gap of substrate 10.

Without being bound to a particular theory, in the solar cell device of FIG. 2, high energy photons incident upon emitter layer 24 generate electron-hole pairs. Any remaining high energy photons that pass through the emitter and the p-n junction regions can generate electron-hole pairs in base layer 22 as well. Minority carriers are accelerated towards the junction region due to the presence of built-in fields 30. Low energy photons can be absorbed in nano-structured region 28. Photons with energies below the energy gap of substrate 10 will pass through substrate 10 and can be reflected by back reflector 36.

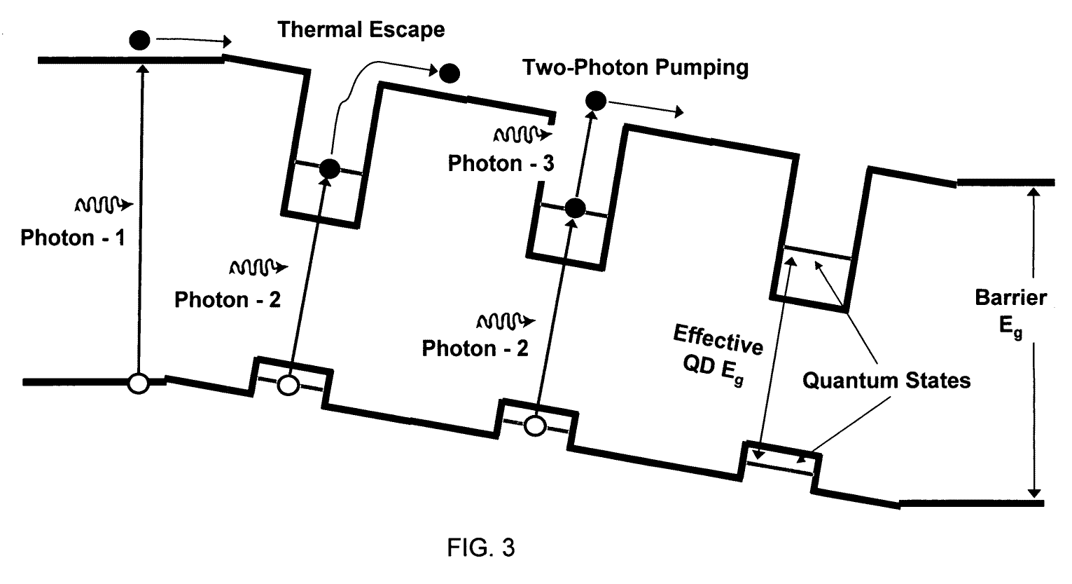

Without being bound to a particular theory, potential absorption of photons and collection processes of photon-generated current in a solar cell device of the invention, employing nano-structured region 28, are shown in FIG. 3. FIG. 3 illustrates the additional photon collection mechanisms available when quantum wells or quantum dots are inserted into the p-n junction depletion region of a barrier semiconductor. In a standard solar cell, only photons with energy above that of the barrier semiconductor energy gap are absorbed and collected. In a quantum well or quantum dot solar cell, lower photon energies can be collected. For example, photons with energies above the effective quantum well energy gap can be absorbed and collected via a thermal escape process. Even higher conversion efficiencies can be achieved with two photon absorption processes that pump electrons directly into the conduction band (see, for example, Luque, Antonio, and Marti, Antonio, “Increasing the Efficiency of Ideal Solar Cells by Photon Induced Transitions at Intermediate Levels,” Physical Review Letters, vol. 78, pp. 5014-5017, June 1997, the entire teachings of which are incorporated herein by reference). Three types of photons and there types of absorption and collection processes are depicted in FIG. 3. Photons with energy above that of the barrier energy gap (Photon-1) can be absorbed in the top barrier layer and collected by diffusion to the junction. Photons with energy above that of the effective quantum energy gap (Photon-2) can be absorbed in the quantum well or dot. The electrons excited into the quantum state can be collected by either thermal escape or by the subsequent excitation by photons with energies above the difference in energy between the barrier and effective quantum energy gap (Photon-3).

Referring back to FIG. 1, in a second embodiment, a solar cell device of the invention further includes nano-structured region 28 at p-n junction 26 of at least one subcell. Features, including specific features, of nano-structured region 28 are as described above in the first embodiment. In particular, in this embodiment, the quantum dots or the quantum wells include InN or InGaN, and the wide band gap matrix includes InGaN, GaN, or AlGaN. Alternatively, the quantum dots or the quantum wells include InAs, GaAs or InGaAs, and the wide band gap matrix includes InGaP, GaAsP, AlGaAs, AlGaInAs or AlGaInP.

In one specific embodiment, the quantum dots or the quantum wells include InN or InGaN, and the wide band gap matrix includes InGaN, GaN or AlGaN; and base layer 22 and/or emitter layer 24 includes a nitride material. Suitable specific examples of nitride materials include AlN, GaN, InN, InGaN or AlGaN, or an alloy thereof. In another specific embodiment, the quantum dots or the quantum wells include InN or InGaN, and the wide band gap matrix includes InGaN, GaN, or AlGaN; and base layer 22 and/or emitter layer 24 includes InGaN, GaN, or AlGaN or an alloy thereof. In these embodiments, InN and the InGaN quantum dots or the quantum wells are preferably self-assembled by the strain-driven Stranski-Krastanov growth known in the art.

In yet another specific embodiment, the quantum dots or the quantum wells include InAs, GaAs or InGaAs; the wide band gap matrix includes InGaP, GaAsP, AlGaAs, AlGaInAs or AlGaInP; and base layer 22 and/or emitter layer 24 includes an arsenide or phosphide material. Suitable specific arsenide or phosphide materials include GaAs, AlAs, InAs, GaP, InP, AlP, InGaAs, InGaP, GaAsP, AlGaAs, AlGaInAs or AlGaInP, or an alloy thereof. In yet another specific embodiment, the quantum dots or the quantum wells include InAs or InGaAs; the wide band gap matrix includes InGaP, GaAsP, AlGaAs, AlGaInAs or AlGaInP; and base layer 22 and/or emitter layer 24 includes InGaP, GaAsP, AlGaAs, AlGaInAs or AlGaInP, or an alloy thereof. In yet another specific embodiment, the quantum dots or the quantum wells include InAs or InGaAs; the wide band gap matrix includes InGaP, GaAsP, AlGaAs, AlGaInAs or AlGaInP; and base layer 22 and/or emitter layer 24 includes GaAs, AlAs, InAs, GaP, InP, or an alloy thereof. In these embodiments, InAs, GaAs and InGaAs quantum dots or the quantum wells are preferably self-assembled by the strain-driven Stranski-Krastanov growth known in the art.

Optionally, the solar cell device of the second embodiment can further includes one or more photon reflector structures 32 (not shown in FIG. 1). Features, including specific features, of photon reflector structure 32 are as described above in the first embodiment. Photon reflector structure 32 can be placed between substrate 10 and p-n diode component 20; over substrate 20 and opposite p-n diode component 20; or over p-n diode component 20 and opposite substrate 10.

In the solar cell device of the second embodiment, optionally, base layer 22 and/or emitter layer 24 (i.e. n-type semiconductor layer and/or p-type semiconductor layer) of at least one subcell includes either a compositional grade or a doping grade, or both, thereby having built-in quasi-electric field 30. Features, including specific features, of built-in quasi-electric field 30 are as described above in the first embodiment.

Optionally, the solar cell device of the second embodiment includes one or more photon reflector structures 32, and further includes base layer 22 and/or emitter layer 24 of at least one subcell, having built-in quasi electric field 30. Features, including specific features, of built-in quasi electric field 30 and photon reflector structure 32 are as described above in the first embodiment.

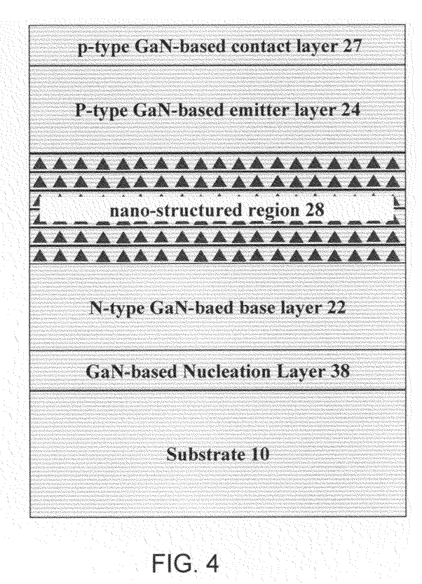

FIG. 4 shows one, further specific embodiment of the invention, employing GaN-based epitaxial layers. The GaN-based epitaxial layers include: (a) GaN or AlGaN nucleation layer 38, (b) n-type GaN or AlGaN base layer 22, (c) nano-structured region 28 including a series of layers including InN or InGaN quantum dots capped with a wider band gap material, such as GaN, InGaN, or AlGaN, (d) p-type GaN or AlGaN emitter layer 24, and (e) p-type GaN contact layer 27. In one example, the GaN-based epitaxial layers include AlGaN nucleation layer 38, n-type AlGaN base layer 22, InN or quantum dots or wells embedded within GaN, p-type AlGaN emitter layer 24, and p-type GaN contact layer 27. The InN or InGaN quantum dots are preferably self-assembled quantum dot layers grown by, for example, the strain-induced Stranski-Krastanov growth mechanism (see, for example, Ng, Y. F., et al., “Growth Mode and Strain Evolution During InN Growth on GaN(0001) by Molecular-beam Epitaxy,” Applied Physics Letters, 81(21): 3960-3962 (2002) (the entire teachings of which are incorporated herein by reference).

The composition and/or the doping level in emitter and base layers 22 and 24 of FIG. 4 each and independently can be graded to create built-in quasi-electric fields 30 that can push minority carriers toward the emitter-base junction.

In the solar cell device of FIG. 4, the GaN-based epitaxial layers can be grown on a sapphire substrate or a silicon substrate. When a sapphire substrate is used, which is highly transparent to almost the entire solar spectrum, the solar cell device of FIG. 4 can be operated with either top or bottom solar incidence. Preferably, when a sapphire substrate is used, photons are incident at the bottom of the structure through the transparent sapphire substrate. In this case, one or more photon reflectors 32 can be added to the top of the epitaxial structure. When a silicon substrate is used, which can absorb much of the solar spectrum, preferably, the solar cell device of FIG. 4 has photons incident upon the top of the epitaxial structure. In this case, one or more reflectors 32, such as DBRs 34, can be added between nucleation layer 38 and the silicon substrate.

It is noted that while FIG. 4 depicts a structure with a p-type emitter layer over an n-type base layer, those skilled in the art will readily recognize that the same basic device structure could be employed with an n-type emitter layer over a p-type base layer.

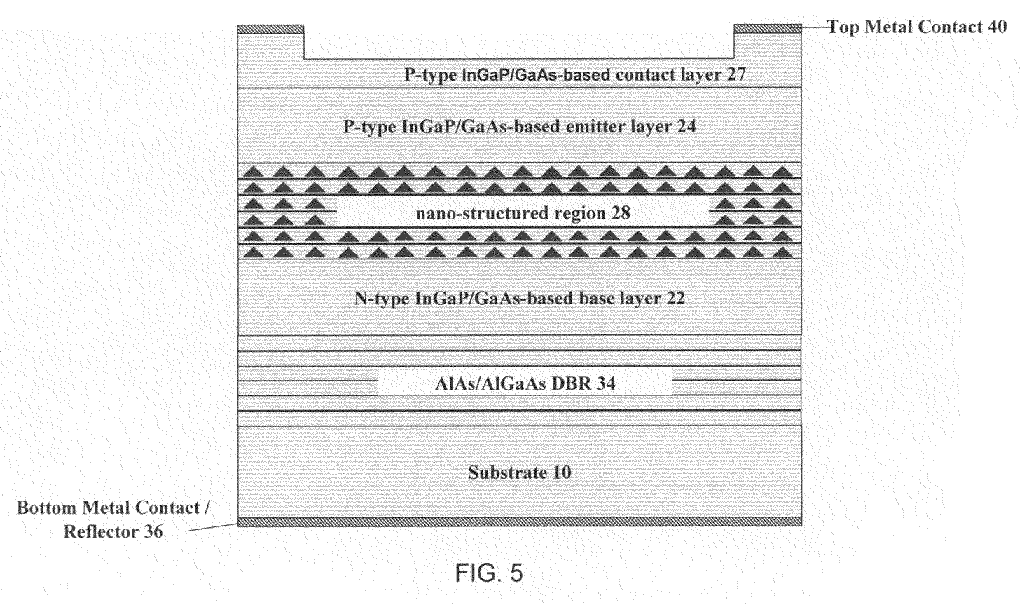

FIG. 5 shows another, further specific embodiment of the invention, employing InGaP/GaAs-based epitaxial layers. The InGaP/GaAs-based epitaxial layers include: (a) AlAs/AlGaAs DBR 34, (b) n-type AlInGaP base layer 22, (c) nano-structured region 28 that includes a series of layers including InAs or InGaAs quantum dots capped with a wider band gap material such as InGaP, (d) p-type AlGaAs or AlInGaP emitter layer 24, and (e) p-type GaAs contact layer 27. In one example, the InGaP/GaAs-based epitaxial layers include AlAs/AlGaAs DBR 34, n-type AlInGaP base layer 22, InGaAs quantum dots or wells embedded within InGaP, p-type AlGaAs emitter layer 24, and p-type GaAs contact layer 27. In another example, the InGaP/GaAs-based epitaxial layers include n-type InGaP base layer 22, GaAs and InGaAs quantum dots or wells embedded within InGaP, p-type AlGaAs emitter layer 24, and p-type GaAs contact layer 27. The InAs and InGaAs quantum dots are preferably self-assembled quantum dot layers grown by, for example, the strain-induced Stranski-Krastanov growth mechanism (see, for example, Bruce A. Joyce and Dimitri D. Vvedensky, “Self-organized Growth on GaAs Surfaces,” Materials Science and Engineering R 46 (2004) 127-176).

The composition and/or the doping level in emitter and base layers 22 and 24 of FIG. 5 can each and independently be graded to create built-in quasi-electric fields 30 that can push minority carriers toward the emitter-base junction.

In the solar cell device of FIG. 5, the InGaP/GaAs-based epitaxial layers can be grown on a GaAs substrate or a silicon substrate. Because these substrates generally are absorbing much of the solar spectrum, preferably, photons are incident upon the top epitaxial layers.

The solar cell device of FIG. 5 can further include one or more photon reflectors 32 (e.g., back reflector 36 and DBR 34). Specifically, the solar cell device of FIG. 5, photons are incident upon the top of the InGaP/GaAs-based epitaxial layers. Photon reflectors 32, such as DBRs 34 (e.g., AlAs or AlGaAs DBR), can be tuned to reflect photons with energies just above 1.42 eV, the energy gap of the GaAs substrate.

The solar cell device of FIG. 5 can also include top and bottom metal contacts 40. As shown in FIG. 5, the bottom metal contact can be included into the reflectors at the bottom of the substrate. Alternatively, the bottom metal contact can be included separately from photon reflectors 32 (not shown in FIG. 5). To minimize unwanted absorption, preferably, the top metal contact area can be minimized and the GaAs contact layer etched away in areas not contacting the metal layer.

When the solar cell device of FIG. 5 employs a silicon substrate, additional nucleation and buffer layers can be inserted between the silicon substrate and DBR 34 (e.g., AlAs or AlGaAs DBR). These nucleation and buffer layers are preferably non-absorbing. Also, DBR 34 can be tuned to reflect photons above the silicon energy gap of 1.12 eV. Typically, the minority carrier lifetime of III-V materials grown on silicon is always degraded. Application of built-in quasi-electric fields 30 to emitter and base layers 22 and 24 over silicon substrate 10 can greatly improve the solar cell device performance.

It is noted that while FIG. 5 depicts a structure with a p-type emitter layer over an n-type base layer, those skilled in the art will readily recognize that the same basic device structure could be employed with an n-type emitter layer over a p-type base layer.

The solar cell devices of the invention can employ a single p-n junction subcell. Alternatively, the solar cell devices of the invention can employ a plurality of p-n junction subcells connected to each other. The subcells can be connected in series or in parallel. If the subcells are connected in series, the total current will be limited by the subcell generating the least amount of current. This current-matching requirement of series-connected devices makes state-of-the-art multi-junction cells more challenging to design than single-junction devices and highly susceptible to changes in the solar spectrum throughout the day and from location to location. If the subcells are connected in parallel (e.g., in an n-p-n configuration or in an p-n-p configuration), the operating voltage will be limited by the subcell generating the lowest voltage.

In a fourth embodiment, a solar cell device of the invention is a multi-junction solar cell device that includes at least two subcells, wherein the solar cell device includes the features described above in the first, second or third embodiment, e.g., nano-structured region 28, built-in quasi-electric field 30 and/or photon reflector structure 32.

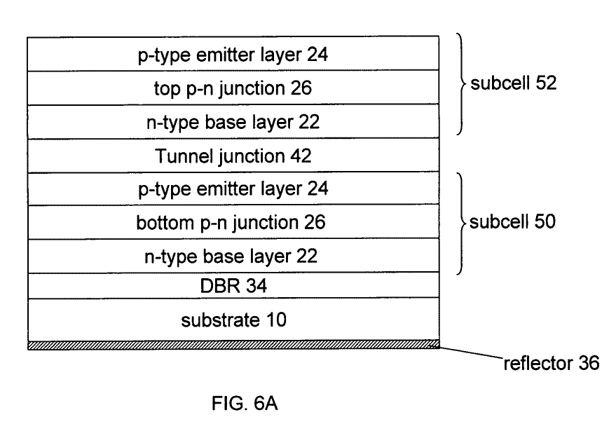

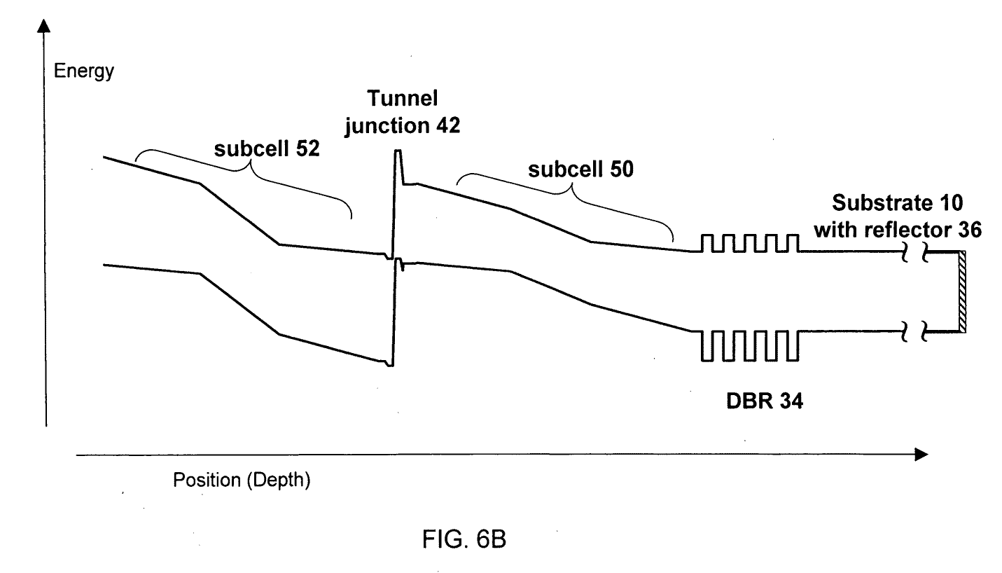

FIGS. 6A and 6B show one example of the fourth embodiment. FIG. 6A shows a cross-sectional view of a multi-junction solar cell of the invention. FIG. 6B shows the multi-junction solar cell of FIG. 6A in view of energy. In the device of FIGS. 6A and 6B, first subcell 50 and second subcell 52 are connected via tunnel junction 42. Alternatively, first subcell 50 and second subcell 52 can be each independently connected via a metal contact(s) (not shown in FIGS. 6A and 6B) instead of tunnel junction 42. Although only first and second subcells 50 and 52 are included in the device of FIGS. 6A and 6B, additional subcells can be added to the device of FIGS. 6A and 6B. Features, including specific features of, first and second subcells 50 and 52, and components thereof, are as described above, for example, with respect to FIGS. 2-5.

Suitable examples of materials for base layer 22 and emitter layer 26 of each of subcells 50 and 52 are as described above. Specifically, second subcell 52 includes a wide band gap material, such as AlGaAs or AlGaInP, while first subcell 50 includes a lower energy gap material, such as InGaAs or AlGaInAs.

Suitable examples for substrate 10 of the device of FIGS. 6A and 6B are as described above, for example, with respect to FIGS. 2-5. Specifically, the solar cell device of FIGS. 6A and 6B employs either a GaAs substrate or a silicon substrate. When GaAs substrate or a silicon substrate is employed, preferably, photons are incident upon the top epitaxial layers, and one or more back reflectors 36 are further employed.

The dimensions of the junction depletion regions, bottom p-n junction 26 and top p-n junction 26, can be adjusted by both the magnitude of the n- and p-type doping adjacent to the junctions and by adding un-doped (or intrinsic) material between the n- and p-type layers. In one specific embodiment, bottom p-n junction 26 and/or top p-n junction 26 include nano-structured region 28 described above, for example, with respect to FIGS. 2-5.

In another specific embodiment, compositional and/or doping grading can be used to create built-in quasi-electric fields 30, as described above, for example, with respect to FIG. 2, which can push minority carriers towards the junctions.

In another specific embodiment, one or more photon reflector structures 32, such as DBRs and/or metallic back or front reflectors, can be employed to, for example, double the optical path length of photons with energies near that of the material used in junction region of the bottom cell.

It is noted that while FIGS. 6A and 6B each depict a structure with a p-type emitter layer over an n-type base layer, those skilled in the art will readily recognize that the same basic device structure could be employed with an n-type emitter layer over a p-type base layer.

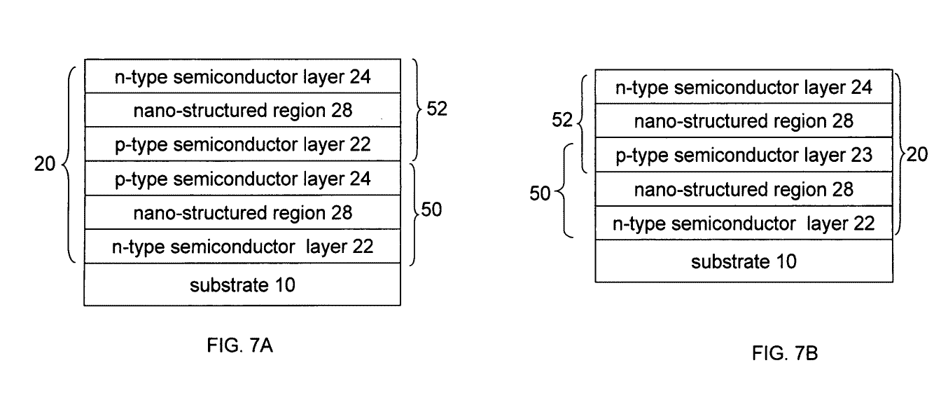

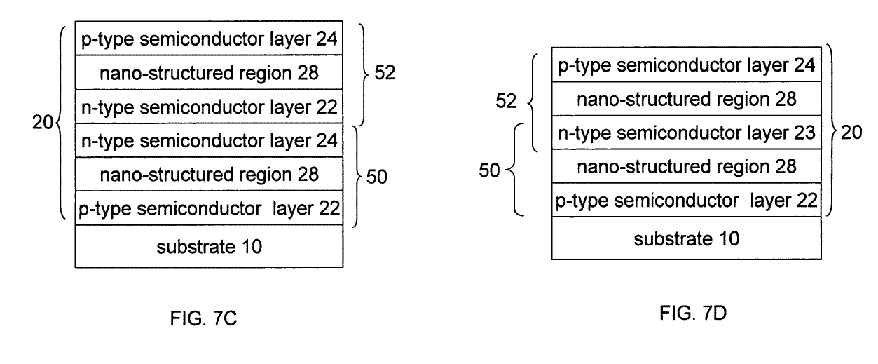

In a fifth embodiment, a solar cell device of the invention is a voltage-matched, dual-junction solar cell device, which is analogous to a standard InGaP hetero-junction bipolar transistor known in the art, for example, in U.S. Pat. No. 6,800,870 (the entire teachings of which are incorporated herein by reference). As shown in FIGS. 7A-7D, in the voltage-matched dual-junction solar cell device, p-n diode component 20 includes first subcell 50 over substrate 10, and second subcell 52 over first subcell 50. Each of subcells 50 and 52 includes base layer 22 and emitter layer 24 to form a p-n junction. The solar cell device further includes nano-structured region 28 at the p-n junction. Two subcells 50 and 52 are connected in parallel to each other by the p-type or the n-type semiconductor layer of each subcell. The p-type or the n-type semiconductor layer(s) at the junction of two subcells 50 and 52 can be two separate semiconductor layers which are included in subcells 50 and 52, respectively (see, for example, FIGS. 7A and 7C). Alternatively, two subcells 50 and 52 share common p-type or n-type semiconductor layer 23 by which the two subcells are connected to each other (see, for example, FIGS. 7B and 7D). Features, including specific features, of nano-structured region 28 are as described above in the first embodiment.

As shown in FIGS. 7A and 7B, in one specific embodiment of the invention, the voltage-matched, dual-junction solar cell device of the invention, employs an n-p-n structure, in which subcells 50 and 52 are connected to each other by the p-type semiconductor layer of each subcell.

In FIG. 7A, subcells 50 and 52 are connected to each other by p-type semiconductor layer 24 (emitter layer) of subcell 50 and by the p-type semiconductor layer 22 (base layer) of subcell 52. In FIG. 7B, subcells 50 and 52 share common, p-type semiconductor layer 23, and subcells 50 and 52 are connected to each other by common, p-type semiconductor layer 23.

In another specific embodiment, as shown in FIGS. 7C and 7D, the voltage-matched, dual-junction solar cell device of the invention employs an p-n-p structure, in which subcells 50 and 52 are connected to each other by the n-type semiconductor layer of each subcell.

In FIG. 7C, subcells 50 and 52 are connected to each other by n-type semiconductor layer 24 (emitter layer) of subcell 50 and by the n-type semiconductor layer 22 (base layer) of subcell 52. In FIG. 7D, subcells 50 and 52 share common, n-type semiconductor layer 23, and subcells 50 and 52 are connected to each other by common, n-type semiconductor layer 23.

Typically, the voltage-matched, dual-junction solar cell device of the invention can be constructed from two wide-band gap junctions composed of an identical or a nearly identical semiconductor material. In this way, voltage matching can be obtained. Meanwhile, current collection can be optimized by inserting nano-structured region 28 (which includes quantum dots or wells embedded within a wide band gap matrix) into each junction, with the junction furthest away from the incident light containing larger quantum dots or wells, and/or quantum dots or wells with a lower bulk energy gap.

In the voltage-matched, dual-junction solar cell device of the invention, its spectral response and operating voltage can potentially be tuned and tailored in ways that are generally not possible with bulk semiconductor junctions, enabling new device architectures. In particular, two p-n junction subcells with similar dark diode characteristics but different spectral responses can be electrically connected in parallel. As shown in FIG. 7B, parallel electrical interconnection can be achieved monolithically by employing an n-p-n structure. Alternatively, as shown in FIG. 7D, parallel electrical interconnection can be achieved monolithically by employing an n-p-n structure. For example, in the n-p-n structure of FIG. 7B or in the p-n-p structure of FIG. 7D, the top subcell (either subcell 50 or 52), which is proximate to the incident light, employs nano-structured layers that absorb mostly high energy photons, while the bottom subcell (either subcell 52 or 50), which is distal from the incident light, employs nano-structured layers that absorb mostly low energy photons. During device fabrication, electrical contacts can be formed on both semiconductor layers 22 and 24, and common semiconductor layer 23. Two-terminal operation can be achieved by externally connecting the two n-type layers (see FIG. 7B) or two p-type layers (see FIG. 7D) and by applying one voltage simultaneously across both p-n junction subcells. In the devices of FIGS. 7B and 7D, the turn-on voltage of each subcell can be matched, and the total device current of the device during voltage-matched operation would be the sum of the individual subcell currents. As a comparison, in standard structures employing a parallel interconnection, the overall voltage operation would be limited by the subcell having the lowest energy-gap. It is noted that, although construction of nano-structured layers of subcells 50 and 52 and their voltage-matching schemes are described with reference to FIGS. 7B and 7D, the same schemes can be employed for the devices of FIGS. 7A and 7C.

Features, including specific features, of nano-structured region 28, are as described above in the first embodiment. In one specific embodiment, the quantum dots or the quantum wells of nano-structured region 28 include InN or InGaN; and the wide band gap matrix of nano-structured region 28 includes InGaN, GaN, or AlGaN; and the n-type semiconductor layer and/or the p-type semiconductor layer of at least one of subcells 50 and 52 includes a nitride material. Suitable specific examples of nitride materials include AlN, GaN, InN, InGaN or AlGaN, or an alloy thereof. In yet another specific embodiment, the quantum dots or the quantum wells include InN or InGaN, and the wide band gap matrix includes InGaN, GaN, or AlGaN; and the n-type semiconductor layer and/or the p-type semiconductor layer of at least one of subcells 50 and 52 includes InGaN, GaN, or AlGaN or an alloy thereof. In these embodiments, InN and the InGaN quantum dots or the quantum wells are preferably self-assembled by the strain-driven Stranski-Krastanov growth known in the art.

In yet another specific embodiment, the quantum dots or the quantum wells of nano-structured region 28 include InAs, GaAs or InGaAs; the wide band gap matrix of nano-structured region 28 includes InGaP, GaAsP, AlGaAs, AlGaInAs or AlGaInP; and the n-type semiconductor layer and/or the p-type semiconductor layer of at least one of subcells 50 and 52 includes an arsenide or phosphide material. Suitable specific arsenide or phosphide materials include GaAs, AlAs, InAs, GaP, InP, AlP, InGaAs, InGaP, GaAsP, AlGaAs, AlGaInAs or AlGaInP, or an alloy thereof. In yet another specific embodiment, the quantum dots or the quantum wells of nano-structured region 28 include InAs or InGaAs; the wide band gap matrix of nano-structured region 28 includes InGaP, GaAsP, AlGaAs, AlGaInAs or AlGaInP; and the n-type semiconductor layer and/or the p-type semiconductor layer of at least one of subcells 50 and 52 includes InGaP, GaAsP, AlGaAs, AlGaInAs or AlGaInP, or an alloy thereof. In yet another specific embodiment, the quantum dots or the quantum wells of nano-structured region 28 include InAs or InGaAs; the wide band gap matrix of nano-structured region 28 includes InGaP, GaAsP, AlGaAs, AlGaInAs or AlGaInP; and the n-type semiconductor layer and/or the p-type semiconductor layer of at least one of subcells 50 and 52 includes GaAs, AlAs, InAs, GaP or InP, or an alloy thereof. In these embodiments, InAs, GaAs and InGaAs quantum dots or the quantum wells are preferably self-assembled by the strain-driven Stranski-Krastanov growth known in the art.

Optionally, the voltage-matched, dual-junction solar cell device of the invention can further include one or more photon reflector structures 32. Features, including specific features, of photon reflector structure 32 are as described above in the first embodiment. Photon reflector structure 32 can be placed between substrate 10 and p-n diode component 20; over substrate 20 and opposite p-n diode component 20; or over p-n diode component 20 and opposite substrate 10. In one specific embodiment, at least one of the p-type and the n-type semiconductor layers of first subcell 50 includes compositionally-graded AlGaInAs, or doping-graded InGaAs, and wherein at least one of the p-type and the n-type semiconductor layers of second subcell 52 includes compositionally- and doping-graded AlInGaP, or compositionally-and doping-graded InGaP, and wherein substrate 10 includes GaAs or silicon. In another specific embodiment, at least one of the p-type and the n-type semiconductor layers of first subcell 50 includes compositionally- and doping-graded AlGaInAs, or doping-graded GaAs, wherein at least one of the p-type and the n-type semiconductor layers of second subcell 52 includes InGaP, and wherein the substrate includes germanium.

In the voltage-matched, dual-junction solar cell device of the invention, optionally, the n-type semiconductor layer and/or the p-type semiconductor layer of at least one of subcells 50 and 52 can include either a compositional grade or a doping grade, or both, thereby having built-in quasi-electric field 30. Features, including specific features, of built-in quasi-electric field 30 are as described above in the first embodiment.

Optionally, the voltage-matched, dual-junction solar cell device of the invention can include one or more photon reflector structures 32, and further include an n-type semiconductor layer and/or a p-type semiconductor layer of at least one of subcells 50 and 52, having built-in quasi-electric field 30. Features, including specific features, of built-in quasi-electric field 30 and photon reflector structure 32 are as described above in the first embodiment.

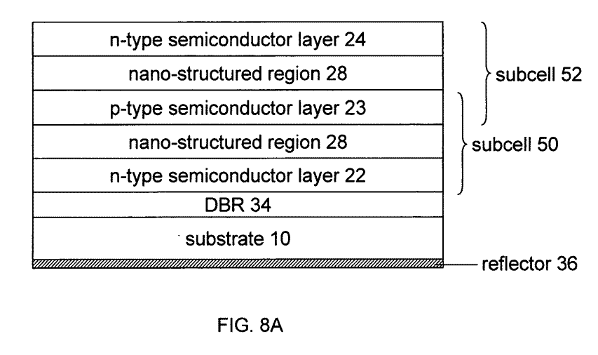

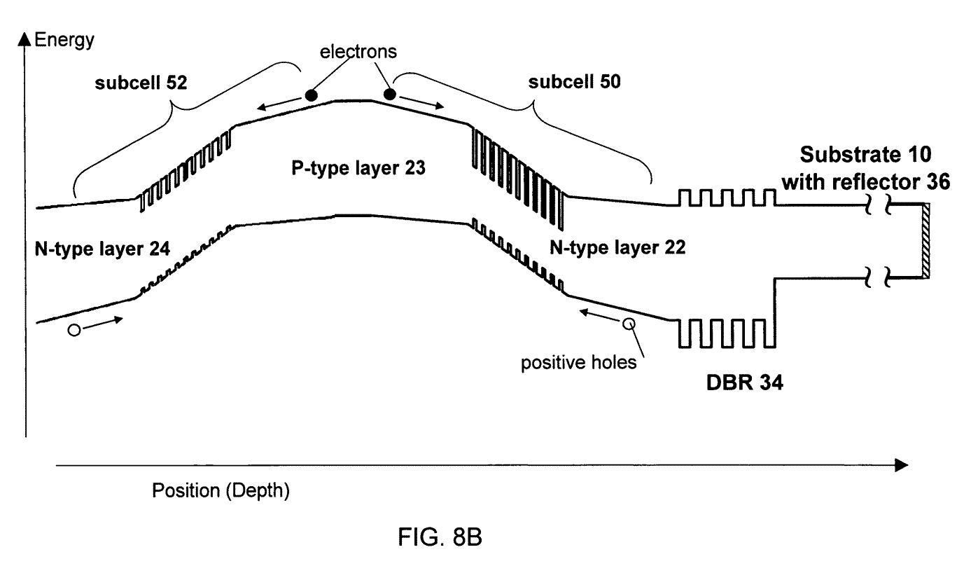

One specific embodiment of the voltage-matched, dual-junction solar cell of the invention is shown in FIGS. 8A and 8B. FIG. 8A shows a cross-sectional view of one embodiment of the voltage-matched, dual-junction solar cell of the invention. FIG. 8B shows the solar cell of FIG. 8A in view of energy.

In the device of FIGS. 8A and 8B, first subcell 50 and second subcell 52 share common p-type semiconductor layer 23, and are connected in parallel in an n-p-n configuration. Specifically, n-type semiconductor layers 22 and 24 of subcells 50 and 52, respectively, include a graded (compositionally graded and/or doping-graded) n-type layer. Specifically, common p-type semiconductor layer 23 is compositionally graded (see FIG. 8B).

In one specific embodiment of the solar cell device of FIGS. 8A and 8B, common p-type semiconductor layer 23 includes AlGaAs. In another specific embodiment, common p-type semiconductor layer 23 includes AlGaAs, and the n-type semiconductor layers of first and second subcells 50 and 52 each independently include AlInGaP. In a further specific embodiment, the p-type AlGaAs semiconductor layer is compositionally graded to have the highest aluminum concentration and the highest p-type doping concentration in the middle region of the p-type semiconductor layer. In another, further specific embodiment, the n-type AlInGaP semiconductor layers of first and second subcells 50 and 52 are each and independently compositionally graded to have the highest aluminum concentration and the highest n-type doping concentration at a region distal from the p-n junction of each subcell.

In another specific embodiment of the solar cell device of FIGS. 8A and 8B, nano-structured region 28 is included at the bottom p-n junction of first subcell 50 and/or at the top p-n junction of second subcell 52. For example, quantum dots or quantum wells composed of InAs or InGaAs can be inserted into the top and/or bottom junction regions. In yet another specific embodiment, nano-structured regions 28 are disposed at the bottom and top p-n junctions, and the nano-structured regions each and independently include quantum dots or quantum wells composed of InAs or InGaAs. Preferably, when solar incidence is assumed to be upon the p-n junction of second subcell 52 (top junction), preferably, nano-structured region 28, disposed at the bottom junction (i.e., at the p-n junction of first subcell 50), employs InGaAs quantum dots or wells having a higher indium composition than does nano-structured region 28 disposed at the top junction (i.e., at the p-n junction of second subcell 52). Alternatively, nano-structured region 28, disposed at the bottom junction (i.e., at the p-n junction of first subcell 50), employs InAs quantum dots having a larger size than that of InAs quantum dots employed in nano-structured region 28 disposed at the top junction (i.e., at the p-n junction of second subcell 52). Alternatively, identical quantum dots or wells can be used in both of the top and bottom junctions.

To further enhance low photon energy absorption in the junction, photon reflector structures, such as a DBR and a back reflector, can be added into the solar cell device of FIGS. 8A and 8B.

Suitable examples for substrate 10 of the device of FIGS. 8A and 8B are as described above. Specifically, the solar cell device of FIGS. 8A and 8B employs either a GaAs substrate or a silicon substrate. When GaAs substrate or a silicon substrate is employed, preferably, photons are incident upon the top epitaxial layers, and one or more back reflectors 36 are further employed.

It is noted that while FIGS. 8A and 8B each depict a structure with an n-type emitter layer over a p-type base layer, those skilled in the art will readily recognize that the same basic device structure could be employed with a p-type emitter layer over an n-type base layer.

The semiconductor layers employed in the invention can be prepared using any suitable method known in the art, such as a metalorganic chemical vapor deposition (MOCVD) epitaxial growth system. Examples of suitable MOCVD epitaxial growth systems are AIXTRON 2400® and AIXTRON 2600® production platforms. For example, a semiconductor layer, such as base layer 22, that includes a Group III-V material can be formed by flowing organometallic compounds over a surface of a layer supporting the semiconductor layer (e.g., substrate 10), depositing atoms of Group III-V of the Periodic Table. A flow rate of each of the organometallic compounds changes during deposition to thereby form a graded band gap throughout the semiconductor layer. The p-dopant and n-dopant concentrations can each and independently be controlled by changing the flow rates of the organometallic compounds. Alternatively, an extrinsic source can also be used simultaneously with an intrinsic source from the organometallic compounds. A typical p-dopant is carbon. A typical n-dopant is silicon.

### EQUIVALENTS

While this invention has been particularly shown and described with references to preferred embodiments thereof, it will be understood by those skilled in the art that various changes in form and details may be made therein without departing from the scope of the invention encompassed by the appended claims.

What is claimed is:

1. A solar cell device, comprising:
a) a substrate; and
b) a p-n diode component that includes at least one subcell and is over the substrate, each subcell including an n-type semiconductor layer and a p-type semiconductor layer to form a p-n junction,
wherein the solar cell device further includes at least two features selected from:
i) a nano-structured region at the p-n junction between the n-type and the p-type semiconductor layers of at least one subcell, the nano-structured region including a plurality of quantum dots or quantum wells that are embedded within a wide band gap matrix that has a band gap greater than that of the quantum dots or the quantum wells embedded therein;
ii) an n-type and/or a p-type semiconductor layer of at least one subcell that includes either a compositional grade or a doping grade, or both, thereby having a built-in quasi-electric field; and
iii) a photon reflector structure between the substrate and the p-n diode component, over the substrate opposite the p-n diode component, or over the p-n diode component opposite the substrate.

2. The solar cell device of claim 1, wherein at least one subcell includes the nano-structured region.

3. The solar cell device of claim 2, wherein the n-type and/or the p-type semiconductor layer of at least one subcell includes either a compositional grade or a doping grade, or both.

4. The solar cell device of claim 3, wherein i) the quantum dots or the quantum wells include InN or InGaN, and the wide band gap matrix includes InGaN, GaN, or AlGaN, or ii) the quantum dots or the quantum wells include InAs, GaAs or InGaAs, and the wide band gap matrix includes InGaP, GaAsP, AlGaAs, AlGaInAs or AlGaInP.

5. The solar cell device of claim 4, wherein the quantum dots or the quantum wells include InN or InGaN, and the wide band gap matrix includes InGaN, GaN, or AlGaN, and wherein the n-type and/or the p-type semiconductor layer includes a nitride material.

6. The solar cell device of claim 5, wherein the nitride material is AlN, GaN, InN, InGaN or AlGaN, or an alloy thereof.

7. The solar cell device of claim 4, wherein the quantum dots or the quantum wells include InAs, GaAs or InGaAs, and the wide band gap matrix includes InGaP, GaAsP, AlGaAs, AlGaInAs or AlGaInP, and wherein the n-type and/or the p-type semiconductor layer includes an arsenide or phosphide material.

8. The solar cell device of claim 7, wherein the arsenide or phosphide material is GaAs, AlAs, InAs, GaP, InP, AlP, InGaAs, InGaP, GaAsP, AlGaAs, AlGaInAs or AlGaInP, or an alloy thereof.

9. The solar cell device of claim 2, wherein the solar cell device further includes a photon reflector structure between the substrate and the p-n diode component; over the substrate and opposite the p-n diode component; or over the p-n diode component and opposite the substrate.

10. The solar cell device of claim 9, wherein the photon reflector structure includes a metallic layer, a distributed Bragg reflector, a total internal reflector, or an omni-directional reflector.

11. The solar cell device of claim 10, wherein the photon reflector structure includes a metallic layer, and wherein the photon reflector is disposed over the substrate and opposite the p-n diode component.

12. The solar cell device of claim 11, wherein the substrate includes GaP, ZnSe or ZnS.

13. The solar cell device of claim 10, wherein the photon reflector structure is disposed between the substrate and the p-n diode component, and includes a distributed Bragg reflector that includes AlAs, AlGaAs, AlGaInP, or AlInP.

14. The solar cell device of claim 9, wherein i) the quantum dots or the quantum wells include InN or InGaN, and the wide band gap matrix includes InGaN, GaN, or AlGaN, or ii) the quantum dots or the quantum wells include InAs GaAs or InGaAs, and the wide band gap matrix includes InGaP, GaAsP, AlGaAs, AlGaInAs or AlGaInP.

15. The solar cell device of claim 14, wherein the quantum dots or the quantum wells include InN or InGaN, and the wide band gap matrix includes InGaN, GaN, or AlGaN, and wherein the n-type and/or the p-type semiconductor layer includes a nitride material.

16. The solar cell device of claim 15, wherein the nitride material is AlN, GaN, InN, InGaN or AlGaN, or an alloy thereof.

17. The solar cell device of claim 14, wherein the quantum dots or the quantum wells include InAs GaAs or InGaAs, and the wide band gap matrix includes InGaP, GaAsP, AlGaAs, AlGaInAs or AlGaInP, and the n-type and/or the p-type semiconductor layer includes an arsenide or phosphide material.

18. The solar cell device of claim 17, wherein the arsenide or phosphide material is GaAs, AlAs, InAs, GaP, InP, AlP, InGaAs, InGaP, GaAsP, AlGaAs, AlGaInAs or AlGaInP, or an alloy thereof.

19. The solar cell device of claim 1, wherein the n-type and/or the p-type semiconductor layer of at least one subcell includes either a compositional grade or a doping grade, or both.

20. The solar cell device of claim 19, wherein the n-type and/or the p-type semiconductor layer independently includes AlGaInAs, InGaAs, AlInGaP, AlGaN or AlGaAs.

21. The solar cell device of claim 20, wherein the n-type and/or the p-type semiconductor layer independently includes compositionally-graded AlGaInAs, doping-graded InGaAs, or compositionally- and doping-graded AlInGaP.

22. The solar cell device of claim 19, wherein the solar cell device further includes the photon reflector structure between the substrate and the p-n diode component; over the substrate and opposite the p-n diode component; or over the p-n diode component and opposite the substrate.

23. The solar cell device of claim 22, wherein the photon reflector structure includes a metallic layer, a distributed Bragg reflector, a total internal reflector, or an omni-directional reflector.

24. The solar cell device of claim 23, wherein the photon reflector structure includes a metallic layer, and wherein the photon reflector is disposed over the substrate opposite the p-n diode component.

25. The solar cell device of claim 24, wherein the substrate includes GaP, ZnSe or ZnS.

26. The solar cell device of claim 23, wherein the photon reflector structure is disposed between the substrate and the p-n diode component, and includes a distributed Bragg reflector that includes AlAs, AlGaAs, AlGaInP, or AlInP.

27. The solar cell device of claim 1, wherein the p-n diode component includes a plurality of the subcells.

28. The solar cell device of claim 27, wherein the solar cell device further comprises a photon reflector structure between the substrate and the p-n diode component, over the substrate opposite the p-n diode component, or over the p-n diode component opposite the substrate.

29. The solar cell device of claim 27. wherein at least one of the subcells includes the nano-structured region.

30. The solar cell device of claim 29, wherein i) the quantum dots or the quantum wells include InN or InGaN, and the wide band gap matrix includes InGaN, GaN, or AlGaN, or ii) the quantum dots or the quantum wells include InAs, GaAs or InGaAs, and the wide band gap matrix includes InGaP, GaAsP, AlGaAs, AlGaInAs or AlGaInP.

31. The solar cell device of claim 27, wherein the n-type and/or the p-type semiconductor layer of at least one subcell includes either a compositional grade or a doping grade, or both.

32. The solar cell device of claim 31, wherein the p-n diode component includes a first subcell proximate to the substrate, and a second subcell distal from the substrate.

33. The solar cell device of claim 32, wherein at least one of the n-type and the p-type semiconductor layers of the first subcell includes compositionally-graded AlGaInAs, or doping-graded InGaAs, and wherein at least one of the n-type and/or the p-type semiconductor layers of the second subcell includes compositionally- and doping-graded AlInGaP, or compositionally- and doping-graded InGaP, and wherein the substrate includes GaAs or silicon.

34. The solar cell device of claim 32, wherein at least one of the n-type and/or the p-type semiconductor layers of the first subcell includes compositionally- and doping-graded AlGaInAs, or doping-graded GaAs, wherein at least one of the n-type and/or the p-type semiconductor layers of the second subcell includes InGaP, and wherein the substrate includes germanium.

35. The solar cell device of claim 34, wherein the quantum dots or the quantum wells include InAs, GaAs or InGaAs, and the wide band gap matrix includes InGaP, AlGaAs or AlGaInAs.

36. The solar cell device of claim 31, wherein at least one of the subcells includes the nano-structured region.

37. The solar cell device of claim 31, wherein the solar cell device further comprises a photon reflector structure between the substrate and the p-n diode component; over the substrate and opposite the p-n diode component; or over the p-n diode component and opposite the substrate.

38. The solar cell device of claim 37, wherein at least one of the subcells includes the nano-structured region.

39. A method of preparing a solar cell device that includes a substrate and a p-n diode component over the substrate, comprising at least two steps selected from:
a) forming a nano-structured region at a p-n junction between an n-type semiconductor layer and a p-type semiconductor layer of at least one subcell of the p-n diode component of the solar cell device, the nano-structured region including a plurality of quantum dots or quantum wells that are embedded within a wide band gap matrix that has a band gap greater than that of the quantum dots or the quantum wells embedded therein;
b) forming an n-type and/or p-type semiconductor layer of at least one subcell of the p-n diode component of the solar cell device, the n-type and/or p-type layer including either a compositional grade or a doping grade, or both, thereby having a built-in quasi-electric field; and
c) forming a photon reflector structure between the substrate and the p-n diode component, over the substrate opposite the p-n diode component, or over the p-n diode component opposite the substrate, the p-n diode component including at least one subcell that includes an n-type semiconductor layer and a p-type semiconductor layer to form a p-n junction.

40. The method of claim 39, wherein the method includes the steps of:
a) forming the nano-structured region; and
b) forming the base layer and/or the emitter layer that includes either a compositional grade or a doping grade, or both.

41. The method of claim 39, wherein the method includes the steps of:
a) forming the nano-structured region; and
b) forming the photon reflector structure between the substrate and the p-n diode component, over the substrate opposite the p-n diode component, or over the p-n diode component opposite the substrate.

42. The method of claim 39, wherein the method includes the steps of:
a) forming the base layer and/or the emitter layer that includes either a compositional grade or a doping grade, or both; and
b) forming the photon reflector structure between the substrate and the p-n diode component; over the substrate and opposite the p-n diode component; or over the p-n diode component and opposite the substrate.

43. The method of claim 42, wherein the method includes the steps of:
a) forming the nano-structured region;
b) forming the base layer and/or the emitter layer that includes either a compositional grade or a doping grade, or both; and
c) forming the photon reflector structure between the substrate and the p-n diode component; over the substrate and opposite the p-n diode component; or over the p-n diode component and opposite the substrate.

44. A solar cell device, comprising:
a) a substrate; and
b) a p-n diode component over the substrate, the p-n diode component including at least two subcells, each subcell including an n-type semiconductor layer and a p-type semiconductor layer to form a p-n junction,
wherein the subcells are connected in parallel to each other by the p-type or the n-type semiconductor layer of each subcell,
and wherein at least one of the subcells includes a nano-structured region at the p-n junction, the nano-structured region including a plurality of quantum dots or quantum wells that are embedded within a wide band gap matrix that has a band gap greater than that of the quantum dots or the quantum wells embedded therein.

45. The solar cell device of claim 44, wherein the p-n diode component includes a first subcell proximate to the substrate, and a second subcell distal from the substrate.

46. The solar cell device of claim 45, wherein the first and second subcells share a common p-type or an n-type semiconductor layer by which the subcells are connected to each other.

47. The solar cell device of claim 46, wherein the first and second subcells are connected in parallel to each other in an n-p-n configuration in which the common semiconductor layer shared by the two subcells is a p-type semiconductor layer.

48. The solar cell device of claim 46, wherein the subcells are connected in parallel to each other in an p-n-p configuration in which the common semiconductor layer shared by the two subcells is an n-type semiconductor layer.

49. The solar cell device of claim 44, wherein i) the quantum dots or the quantum wells include InN or InGaN, and the wide band gap matrix includes InGaN, GaN, or AlGaN, or ii) the quantum dots or the quantum wells include InAs, GaAs or InGaAs, and the wide band gap matrix includes InGaP, GaAsP, AlGaAs, AlGaInAs or AlGaInP.

50. The solar cell device of claim 49, wherein the quantum dots or the quantum wells include InN or InGaN, and the wide band gap matrix includes InGaN, GaN, or AlGaN, and wherein the p-type or the n-type semiconductor layer includes a nitride material.

51. The solar cell device of claim 50, wherein the nitride material is AlN, GaN, InN, InGaN or AlGaN, or an alloy thereof.

52. The solar cell device of claim 49, wherein the quantum dots or the quantum wells include InAs, GaAs or InGaAs, and the wide band gap matrix includes InGaP, GaAsP, AlGaAs, AlGaInAs or AlGaInP, and wherein the p-type or the n-type semiconductor layer includes an arsenide or phosphide material.

53. The solar cell device of claim 52, wherein the arsenide or phosphide material is GaAs, AlAs, InAs, GaP, InP, AlP, InGaAs, InGaP, GaAsP, AlGaAs, AlGaInAs or AlGaInP, or an alloy thereof.

54. The solar cell device of claim 52, wherein the p-type semiconductor layer of each subcell includes AlGaAs, and wherein the n-type semiconductor layer of each subcell includes AlInGaP.

55. The solar cell device of claim 45, wherein the first and the second subcells share a common p-type or n-type semiconductor layer, and are connected to each other by the common p-type or n-type semiconductor layer.

56. The solar cell device of claim 55, wherein the common p-type or n-type semiconductor layer includes AlGaAs.

57. The solar cell device of claim 56, wherein the common p-type or n-type semiconductor layer is a p-type AlGaAs, and wherein the n-type semiconductor layers of the first and the second subcells each independently include AlInGaP.

58. The solar cell device of claim 57, wherein the n-type semiconductor layer and/or the p-type semiconductor layer of at least one of the subcells includes either a compositional grade or a doping grade, or both.

59. The solar cell device of claim 58, wherein the p-type AlGaAs semiconductor layer is graded to have the highest aluminum concentration and the highest p-type doping concentration in the middle region of the p-type AlGaAs semiconductor layer, and wherein the n-type AlInGaP semiconductor layers of the first and the second subcells are each and independently graded to have the highest aluminum concentration and the highest n-type doping concentration at a region distal from the p-n junction.

60. The solar cell device of claim 59, wherein the quantum dots or the quantum wells include InAs, GaAs or InGaAs, and the wide band gap matrix includes InGaP, AlGaAs or AlGaInAs.

61. The solar cell device of claim 60, wherein each of the first and the second subcells include the nano-structured region at the p-n junction.

62. The solar cell device of claim 61, wherein the nano-structured region of each of the first and second subcell independently includes a plurality of quantum dots or quantum wells that include InAs, GaAs or InGaAs, the quantum dots or quantum wells embedded within in a wide band gap matrix that includes InGaP, AlGaAs or AlGaInAs.

63. The solar cell device of claim 62, wherein the substrate includes GaAs or Si.

64. The solar cell device of claim 56, wherein the common p-type or n-type semiconductor layer is an n-type AlGaAs, and wherein the p-type semiconductor layers of the first and the second subcells each independently include AlInGaP.

65. The solar cell device of claim 64, wherein the n-type semiconductor layer and/or the p-type semiconductor layer of at least one of the subcells includes either a compositional grade or a doping grade, or both.

66. The solar cell device of claim 65, wherein the n-type AlGaAs semiconductor layer is graded to have the highest aluminum concentration and the highest p-type doping concentration in the middle region of the n-type AlGaAs semiconductor layer, and wherein the p-type AlInGaP semiconductor layers of the first and the second subcells are each independently graded to have the highest aluminum concentration and the highest p-type doping concentration at a region distal from the p-n junction.

67. The solar cell device of claim 66, wherein the quantum dots or the quantum wells include InAs, GaAs or InGaAs, and the wide band gap matrix includes InGaP, AlGaAs or AlGaInAs.

68. The solar cell device of claim 67, wherein each of the first and the second subcells include the nano-structured region at the p-n junction.

69. The solar cell device of claim 68, wherein the nano-structured region of each of the first and second subcell independently includes a plurality of quantum dots or quantum wells that include InAs, GaAs or InGaAs, the quantum dots or quantum wells embedded within in a wide band gap matrix that includes InGaP, AlGaAs or AlGaInAs.

70. The solar cell device of claim 69, wherein the substrate includes GaAs or Si.

71. A method of preparing a solar cell device, comprising the step of forming a p-n diode component over a substrate, wherein the p-n diode component includes at least two subcells, each subcell including an n-type semiconductor layer and a p-type semiconductor layer to form a p-n junction, and wherein the subcells are connected in parallel to each other by the p-type or the n-type semiconductor layer of each subcell, and wherein at least one of the subcells includes a nano-structured region at the p-n junction, the nano-structured region including a plurality of quantum dots or quantum wells that are embedded within a wide band gap matrix that has a band gap greater than that of the quantum dots or the quantum wells embedded therein.

72. A solar cell device, comprising:
a) a substrate;
b) a p-n diode component that includes at least one subcell and is over the substrate, each subcell including an n-type semiconductor layer and a p-type semiconductor layer to form a p-n junction;
c) a nano-structured region at the p-n junction, the nano-structured region including a plurality of quantum dots or quantum wells that are embedded within a wide band gap matrix that has a band gap greater than that of the quantum dots or the quantum wells embedded therein, wherein i) the quantum dots or the quantum wells include InN or InGaN, and the wide band gap matrix includes InGaN, GaN, or AlGaN, or ii) the quantum dots or the quantum wells include InAs, GaAs or InGaAs, and the wide band gap matrix includes InGaP, GaAsP, AlGaAs, AlGaInAs or AlGaInP.

73. The solar cell device of claim 72, wherein the quantum dots or the quantum wells include InN or InGaN, and the wide band gap matrix includes InGaN, GaN, or AlGaN, and wherein the n-type and/or the p-type semiconductor layer includes a nitride material.

74. The solar cell device of claim 73, wherein the nitride material is AlN, GaN, InN, InGaN or AlGaN, or an alloy thereof.

75. The solar cell device of claim 72, wherein the quantum dots or the quantum wells include InAs, GaAs or InGaAs, and the wide band gap matrix includes InGaP, GaAsP, AlGaAs, AlGaInAs or AlGaInP, and wherein at least one of the n-type and the p-type semiconductor layers includes an arsenide or phosphide material.

76. The solar cell device of claim 75, wherein the arsenide or phosphide material is GaAs, AlAs, InAs, GaP, InP, AlP, InGaAs, InGaP, GaAsP, AlGaAs, AlGaInAs or AlGaInP, or an alloy thereof.

77. The solar cell device of claim 72, wherein the solar cell device further includes a photon reflector structure between the substrate and the p-n diode component; over the substrate and opposite the p-n diode component; or over the p-n diode component and opposite the substrate.

78. The solar cell device of claim 72, wherein the n-type and/or the p-type semiconductor layer of at least one subcell that includes either a compositional grade or a doping grade, or both, thereby having a built-in quasi-electric field.

79. A method of preparing a solar cell device, comprising the step of forming a p-n diode component over a substrate, wherein the p-n diode component includes:
a) at least two subcells, each subcell including an n-type semiconductor layer and a p-type semiconductor layer to form a p-n junction; and
b) a nano-structured region at the p-n junction, the nano-structured region including a plurality of quantum dots or quantum wells that are embedded within a wide band gap matrix that has a band gap greater than that of the quantum dots or the quantum wells embedded therein, wherein i) the quantum dots or the quantum wells include InN or InGaN, and the wide band gap matrix includes InGaN, GaN, or AlGaN, or ii) the quantum dots or the quantum wells include InAs, GaAs or InGaAs, and the wide band gap matrix includes InGaP, GaAsP, AlGaAs, AlGaInAs or AlGaInP.
